(19) United States
(12) Patent Application Publication
(10) Pub. No.: US 2010/0123200 A1
(43) Pub. Date: May 20, 2010

(54) Semiconductor device and method of manufacturing the same

(75) Inventor: Gen Tsutsui, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/591,040

(22) Filed: Nov. 5, 2009

(30) Foreign Application Priority Data
Nov. 18, 2008 (JP) 294520/2008

(51) Int. Cl. H01L 27/088; H01L 21/8236

(52) U.S. Cl. 257/392; 438/586; 438/275; 257/E27.061; 257/E21.631

(57) ABSTRACT

Provided is a semiconductor device which includes, on the same semiconductor substrate, a first FET and a second FET higher in threshold voltage than the first FET. The first FET includes a first gate insulating film and a first gate electrode. The second FET includes a second gate insulating film and a second gate electrode. The first gate electrode, the second gate insulating film, and the second gate electrode contain at least one metal element selected from the group consisting of Hf, Zr, Al, La, Pr, Y, Ta, and W. Concentration of the at least one metal element at an interface between the second gate insulating film and the second gate electrode in the second FET is higher than concentration of the at least one metal element at an interface between the first gate insulating film and the first gate electrode in the first FET.

### BACKGROUND OF THE INVENTION

1. Field of the Invention

The present invention relates to a semiconductor device and a method of manufacturing the same. More particularly, the present invention relates to a semiconductor device that includes field effect transistors having different threshold voltages on the same semiconductor substrate, and a method of manufacturing the semiconductor device.

2. Description of the Related Art

In embedded DRAMs and other similar LSIs, a plurality of field effect transistors (FETs) having different threshold voltages are formed on the same semiconductor substrate.

One way to control the threshold voltage of an FET is to adjust the amount of impurities implanted in the FET' s channel region as disclosed in JP 06-222387 A, for example. However, when the threshold voltage is controlled solely by adjusting the channel impurity amount, the increased amount of impurities implanted in the channel region leads to impurity scattering, which causes a lowering in ON current and an increase in gate-induced drain leakage (GIDL) current. JP 06-222387 A therefore proposes a technology of lowering the threshold voltage of a P-channel FET by making a gate insulating film of the P-channel FET thinner than that of an N-channel FET.

JP 2007-281027 A discloses a technology of controlling the threshold voltage by adjusting the amount of impurities in an extension region of a FET that has a lightly doped drain (LDD) structure. This method, too, causes an increase in GIDL current because of the increased impurity amount in the extension region.

JP 2006-93670 A discloses a technology of raising the threshold voltage by allowing Hf, Zr, Al, La, or the like to be present at given concentration at the interface between a gate electrode and a gate insulating film. This method is supposed to be capable of reducing the impurity amount in the channel region.

As mentioned above, increasing the impurity amount in a channel region in order to control the threshold voltage of an FET gives rise to a problem in that impurity scattering causes a lowering in ON current and an increase in GIDL current. Similarly, increasing the impurity amount in an extension region of an FET that has an LDD structure causes the problem of increased GIDL current.

Applying the technology of JP 2006-93670 A to a semiconductor device that has a low-threshold voltage FET and a high-threshold voltage FET on the same substrate causes the following problem.

FIG. 7A is a schematic graph illustrating a relation between channel dose and the threshold voltage in a semiconductor device that has a low-threshold voltage FET (LVT in FIG. 7A) and a high-threshold voltage FET (HVT in FIG. 7A) on the same substrate. As illustrated in FIG. 7A, the threshold voltage has conventionally been controlled by implanting impurities in a channel region. When the technology of JP 2006-93670 A is applied to this semiconductor device, allowing Hf or the like to be present at the interface between a gate insulating film and a gate electrode and thereby raising the threshold voltage, the impurity dose in the channel region can be reduced by an amount that corresponds to the rise in threshold voltage. Even when the amount of Hf or the like at the gate insulating film-gate electrode interface is adjusted such that the threshold voltage of the LVT transistor becomes substantially zero, the channel dose of the HVT transistor remains high as illustrated in FIG. 7A. The HVT transistor is therefore still not free from the problem of impurity scattering causing a lowering in ON current and an increase in GIDL current.

### SUMMARY OF THE INVENTION

According to the present invention, there is provided a semiconductor device including, on the same semiconductor substrate: a first field effect transistor; and a second field effect transistor, which is higher in threshold voltage than the first field effect transistor, in which the first field effect transistor includes: a first gate insulating film formed on the semiconductor substrate; and a first gate electrode formed on the first gate insulating film, in which the first gate electrode contains at least one metal element selected from the group consisting of Hf, Zr, Al, La, Pr, Y, Ta, and W, in which the second field effect transistor includes: a second gate insulating film formed on the semiconductor substrate; and a second gate electrode formed on the second gate insulating film, in which the second gate insulating film and the second gate electrode contain the at least one metal element, and in which concentration of the at least one metal element at an interface between the second gate insulating film and the second gate electrode is higher than concentration of the at least one metal element at an interface between the first gate insulating film and the first gate electrode.

Further, according to the present invention, there is provided a method of manufacturing a semiconductor device in which a first field effect transistor and a second field effect transistor, which is higher in threshold voltage than the first field effect transistor, are formed on the same semiconductor substrate, the method including: forming a gate insulating film in a first field effect transistor forming region and a second field effect transistor forming region on the semiconductor substrate; forming a first electrode layer in the first field effect transistor forming region alone; forming in the first field effect transistor forming region and the second field effect transistor forming region a layer of at least one metal element selected from the group consisting of Hf, Zr, Al, La, Pr, Y, Ta, and W; forming a second electrode layer in the first field effect transistor forming region and the second field effect transistor forming region; and subjecting the semiconductor substrate to heat treatment.

In the structure described above, the second field effect transistor is higher in concentration of the at least one metal element such as Hf, Zr, Al, La, Pr, Y, Ta, or W at the gate insulating film-gate electrode interface than the first field effect transistor. The threshold voltage of the second field effect transistor which is higher than that of the first field effect transistor as well as the threshold voltage of the first field effect transistor can therefore be raised without increasing the channel dose.

According to the present invention, the semiconductor device that includes FETs having different threshold voltages on the same semiconductor substrate can reduce the channel dose of the high-threshold voltage FET, which gives the low-threshold voltage FET and the high-threshold voltage FET both high-performance characteristics.

### BRIEF DESCRIPTION OF THE DRAWINGS

In the accompanying drawings:

FIGS. 1A to 1C are sectional views illustrating a semiconductor device according to an embodiment of the present invention;

FIGS. 2A and 2B are sectional views illustrating steps of manufacturing the semiconductor device according to the embodiment of the present invention;

FIGS. 3A and 3B are sectional views illustrating steps of manufacturing the semiconductor device according to the embodiment of the present invention;

FIGS. 4A and 4B are sectional views illustrating steps of manufacturing the semiconductor device according to the embodiment of the present invention;

FIGS. 5A and 5B are sectional views illustrating steps of manufacturing the semiconductor device according to the embodiment of the present invention;

FIGS. 6A and 6B are sectional views illustrating steps of manufacturing the semiconductor device according to the embodiment of the present invention; and

FIGS. 7A and 7B are schematic graphs illustrating a relation between channel dose and threshold voltage.

### DETAILED DESCRIPTION OF THE PREFERRED EMBODIMENT

A preferred embodiment of the present invention is described below in detail with reference to the drawings. The drawings are described with identical components denoted by the same reference symbol, and a redundant description is omitted.

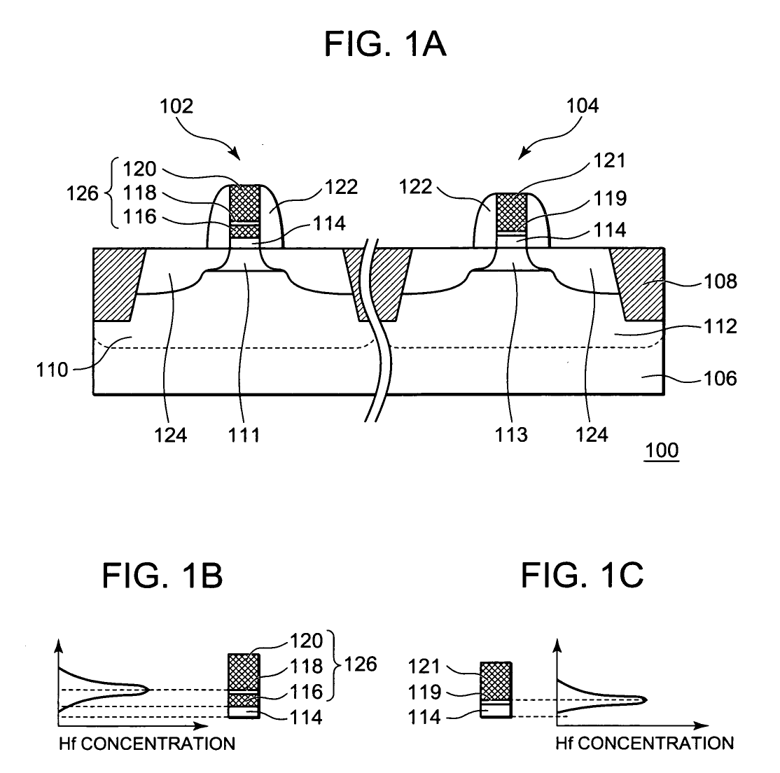

FIG. 1A is a sectional view illustrating a semiconductor device 100 according to this embodiment. FIGS. 1B and 1C are diagrams illustrating Hf concentration profiles in a gate electrode and a gate insulating film.

The semiconductor device 100 includes field effect transistors (FETs) 102 and 104 which are different from each other in threshold voltage on the same semiconductor substrate 106. The threshold voltage of the FET 104 is higher than that of the FET 102. In the following description, the FET 102 and the FET 104 are referred to as an LVT transistor and an HVT transistor, respectively. This embodiment shows an example in which the FETs 102 and 104 are both P-channel FETs.

The LVT transistor 102 includes a gate insulating film 114, which is formed on the semiconductor substrate 106, and a gate electrode 126, which is formed on the gate insulating film 114. The gate electrode 126 includes a lower electrode 116, which is formed on the gate insulating film 114, an upper electrode 120, which is formed above the lower electrode 116, and an Hf layer 118, which is interposed between the lower electrode 116 and the upper electrode 120. Hf is diffused into the lower electrode 116 and the upper electrode 120 through a heat treatment step, which is described later. As illustrated in FIG. 1B, the Hf concentration peak appears in a location within the gate electrode 126 that is apart from the interface between the gate insulating film 114 and the lower electrode 116.

The Hf concentration profile of the gate electrode 126 is such that the Hf concentration decreases from the Hf concentration peak location, which is apart from the interface between the gate insulating film 114 and the gate electrode 126, toward the semiconductor substrate 106 and toward the top surface of the gate electrode 126 (FIG. 1B).

The HVT transistor 104 includes the gate insulating film 114 formed on the semiconductor substrate 106, and a gate electrode 121, which is formed on the gate insulating film 114. A HfSiO layer 119 is interposed between the gate insulating film 114 and the gate electrode 121. Hf is diffused into the gate insulating film 114 and the gate electrode 121 as well through the heat treatment step described later. As illustrated in FIG. 1C, the Hf concentration peak appears between the gate insulating film 114 and the gate electrode 121.

The Hf concentration profile of the gate insulating film 114 in the HVT transistor 104 is such that the Hf concentration decreases from the top surface of the gate insulating film 114 toward the semiconductor substrate 106. The Hf concentration profile of the gate electrode 121 is such that the Hf concentration decreases from the bottom surface of the gate electrode 121 toward the top surface of the gate electrode 121. The HVT transistor 104 is structured such that Hf in the gate insulating film 114 decreases toward the semiconductor substrate 106 and does not reach the semiconductor substrate 106 (FIG. 1C).

As illustrated in FIGS. 1A and 1B, the Hf concentration is higher at the interface between the gate insulating film 114 and the gate electrode 121 in the HVT transistor 104 than at the interface between the gate insulating film 114 and the gate electrode 126 in the LVT transistor 102.

When present between a gate insulating film and a gate electrode, Hf causes a rise in threshold voltage through Fermi pinning. The present invention improves both the characteristics of the LVT transistor and the HVT transistor by controlling the Hf concentration at the gate insulating film-gate electrode interfaces of the LVT transistor and the HVT transistor.

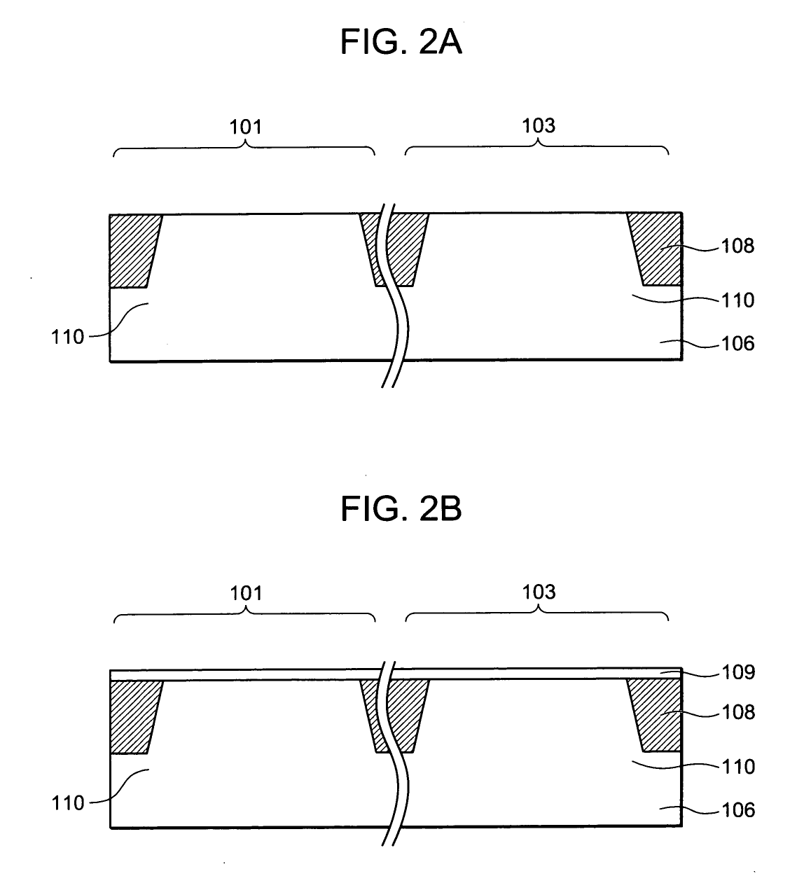

A method of manufacturing the semiconductor device according to the embodiment of the present invention is described next with reference to FIGS. 2A and 2B to FIGS. 6A and 6B.

First, as illustrated in FIG. 2A, a device isolation film 108 is formed on the semiconductor substrate 106. The semiconductor substrate 106 is, for example, a silicon substrate. The device isolation film 108 can be formed by a conventionally used method such as shallow trench isolation (STI) or local oxidation of silicon (LOCOS).

Next, a sacrificial oxide film 109 is formed on the surface of the silicon substrate 106 (FIG. 2B). The sacrificial oxide film 109 is obtained by thermally oxidizing the surface of the silicon substrate 106. The thermal oxidation is accomplished by, for example, performing oxidation treatment for about 100 seconds in an oxygen atmosphere at a temperature of 850° C. An appropriate thickness of the sacrificial oxide film 109 is 5 to 10 nm.

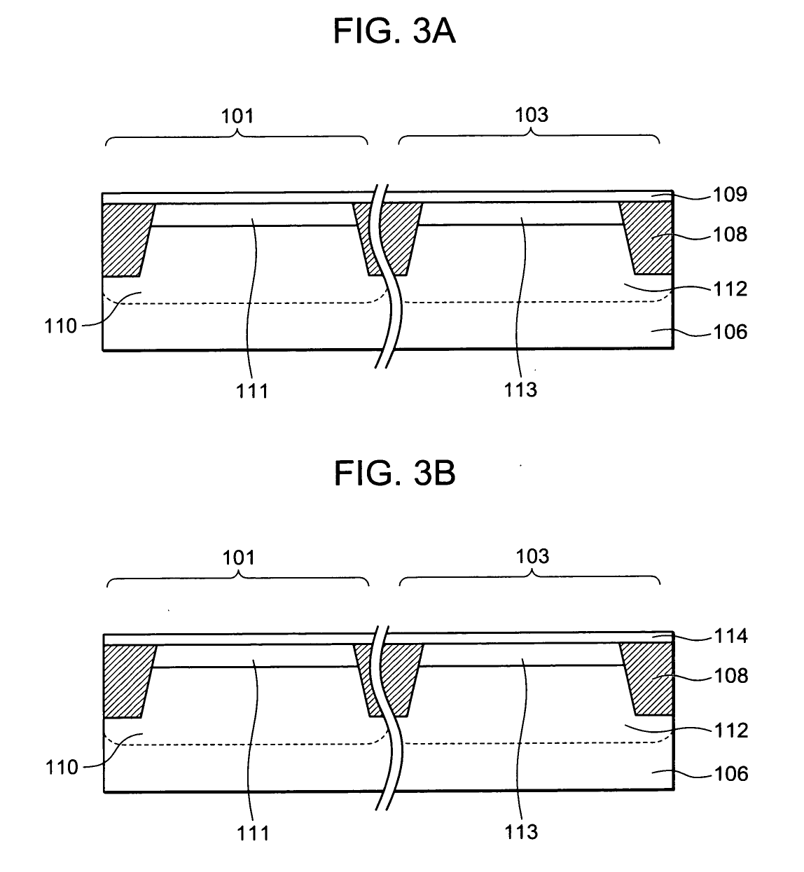

Subsequently, the silicon substrate 106 is doped with N-type impurities in an LVT transistor forming region 101 and an HVT transistor forming region 103 through ion implantation, to thereby form N wells 110 and 112. During the ion implantation, P-well forming regions (not shown) and other regions of the semiconductor substrate 106, in which N wells are not to be formed, are masked with resist or the like. Ion implantation conditions for the N wells 110 and 112 are set such that, for example, phosphorus is implanted at 150 keV and at 1E13 atoms/cm² or more and 5E13 atoms/cm² or less. Impurity ions of given conductivity type are further implanted in the N wells 110 and 112 from above the sacrificial oxide layer 109, to thereby form channel regions 111 and 113 near the surfaces of the N wells 110 and 112 (FIG. 3A). The amounts of the impurities implanted in the channel regions 111 and 113 are determined by how much Hf layer described later adheres, and the amount of adhered Hf layer depends on the threshold voltages of the LVT transistor 102 and the HVT transistor 104, which are set in advance. The impurity amount in the channel region 111 of the LVT transistor 102 and the impurity amount in the channel region 113 of the HVT transistor 104 therefore usually take values different from each other. The channel regions having different impurity amounts are separately implanted with impurities by a known photolithography method with resist or the like being used as a mask.

Next, the channel impurities implanted in the N well 110 and the N well 112 are activated through heat treatment. The heat treatment is performed, for example, for about 10 seconds at a temperature of 1,000° C. The sacrificial oxide film 109 formed on the semiconductor substrate 106 is then removed. Specifically, the sacrificial oxide film 109 is etched away with the use of diluted hydrofluoric acid (for example, HF:H₂O=1:10) and, thereafter, the semiconductor substrate 106 is cleaned with deionized water and dried by nitrogen blow or other drying measures.

A SiON film 114 is next formed as a gate oxide film on the surface of the semiconductor substrate 106 (FIG. 3B). The SiON film 114 can be formed by, for example, rapid thermal oxidation or plasma nitriding. A preferred thickness of the SiON film 114 is, for example, 1.0 nm or more and 2.5 nm or less. The SiON film 114 in this embodiment has a thickness of 2.0 nm. Other than a SiON film, a SiO₂ film may be used as the gate insulating film.

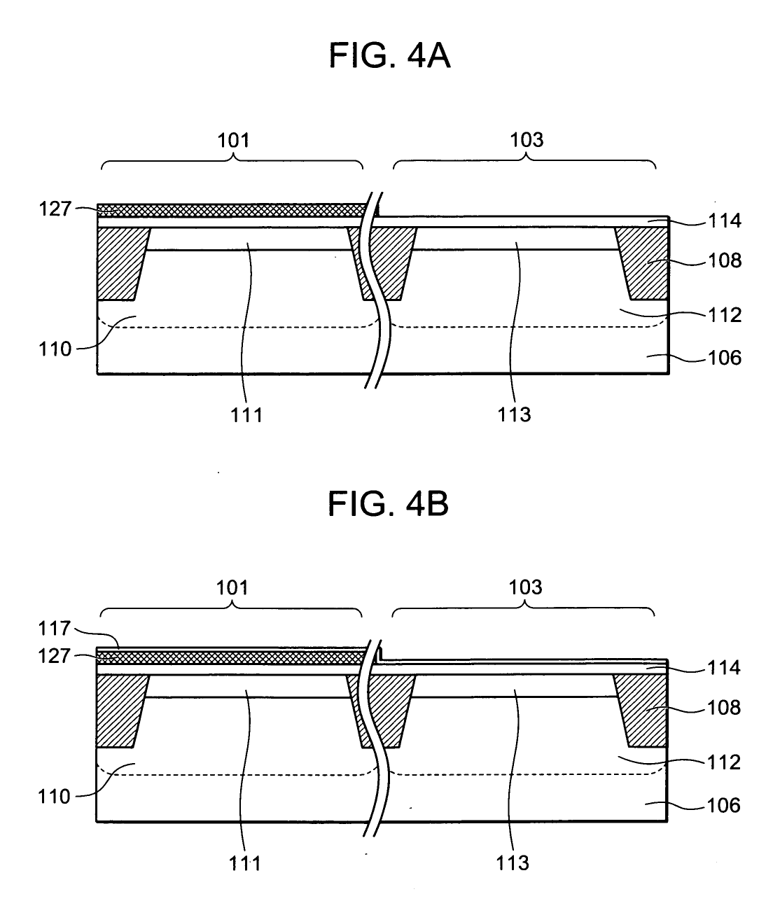

Next, a polysilicon layer is formed on the entire surface of the semiconductor substrate 106 and then removed from the HVT transistor forming region 103, to thereby form a first electrode layer 127 on a part of the SiON film 114 that is in the LVT transistor forming region 101 (FIG. 4A). The polysilicon film is formed by chemical vapor deposition (CVD) and removed with the use of fluoro-nitric acid. The thickness of the first electrode layer 127 is desirably 3 nm to 20 nm, more desirably, 4 nm to 10 nm. Other than polysilicon, amorphous silicon may be used for the first electrode layer 127. Alternatively, a metal material such as Ti or Ta, a conductive material containing Ti such as TiN, or a conductive material containing Ta may be used for the first electrode layer 127.

Next, a Hf layer 117 is adhered to the top surface of the first electrode layer 127 that is in the LVT transistor forming region 101 and to the top surface of the SiON film 114 that is in the HVT transistor forming region 103 (FIG. 4B). The same effect on threshold voltage control as when Hf is employed can be obtained if at least one metal element selected from among Zr, Al, La, Pr, Y, Ta, and W is used. The Hf layer can be formed by, for example, sputtering, or chemical vapor deposition (CVD) or atomic layer deposition (ALD). The amount of Hf adhered needs to be 1×10¹³ atoms/cm² or more and 3×10¹⁵ atoms/cm² or less in surface concentration.

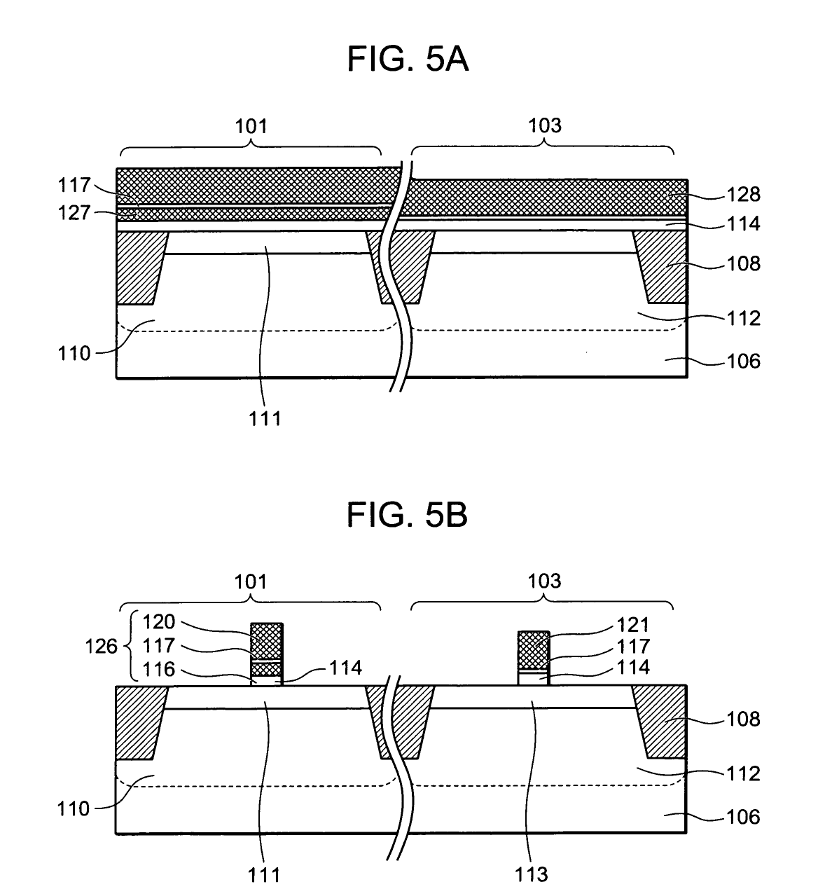

On the Hf layer 117 in the LVT transistor forming region 101 and in the HVT transistor forming region 103, a polysilicon film is formed as the second electrode layer 128 (FIG. 5A). The polysilicon film can be formed by the same methods as the methods described above with regard to the formation of the first electrode layer 127. The second electrode layer 128 corresponds to the upper electrode 120 of the LVT transistor 102 and at the same time corresponds to the gate electrode 121 of the HVT transistor 104. Other than polysilicon, amorphous silicon may be used for the second electrode layer 128. Alternatively, a metal material such as Ti or Ta, a conductive material containing Ti such as TiN, or a conductive material containing Ta may be used for the second electrode layer 128.

Next, selective dry etching is performed on the second electrode layer 128, the Hf layer 117, the first electrode layer 127, and the SiON film 114 in the LVT transistor forming region 101, and on the second electrode layer 128, the Hf layer 117, and the SiON film 114 in the HVT transistor forming region 103, thereby shaping the processed layers into a gate electrode shape (FIG. 5B).

Subsequently, a SiN film (not shown) to serve as an offset spacer is formed on the side and top surfaces of a gate structure that includes the upper electrode 120, the Hf layer 117, the lower electrode 116, and the SiON film 114 in the LVT transistor forming region 101, and on the side and top surfaces of a gate structure that includes the gate electrode 121, the Hf layer 117, and the SiON film 114 in the HVT transistor forming region 103. The surfaces of the gate structures are thus covered. The thickness of the offset spacer (not shown) is, for example, 1 nm or more and 10 nm or less. Extension regions 123 are then formed which are shallow junction regions for improving the short channel characteristics of the transistors. The extension regions 123 are formed by selectively exposing only the regions 123 through photolithography and then performing ion implantation in which BF₂ (in the case of P-channel MOSFETs) is implanted at 2.0 keV and 1E15 atoms/cm².

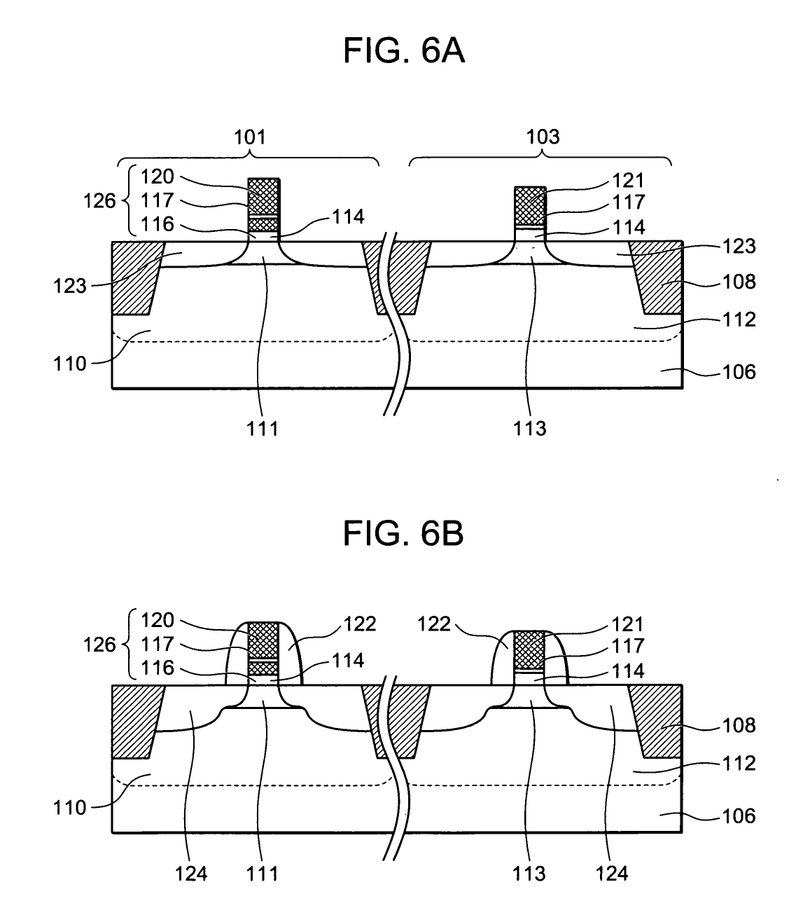

A sidewall insulating film 122 is formed next in the LVT transistor forming region 101 and the HVT transistor forming region 103 on the semiconductor substrate 106 (FIG. 6B). The sidewall insulating film 122 is left only on the side walls of the upper electrode 120, the Hf layer 117, the lower electrode 116, and the SiON film 114 in the LVT transistor forming region 101 which have been processed to have a gate electrode shape, and on the side walls of the gate electrode 121, the Hf layer 117, and the SiON film 114 in the HVT transistor forming region 103 which have also been processed to have a gate electrode shape. This is accomplished by, for example, depositing the insulating material of the sidewall insulating film 122 on the entire surface of the semiconductor substrate 106 and then performing anisotropic etching with the use of fluorocarbon gas or the like.

Next, the gate electrodes 126 and 121 and the sidewall insulating film 122 are used as a mask to dope a region 124 with P-type impurities such as boron (B) to thereby form an impurity diffusion region 124 (FIG. 6B). A source region and a drain region of a P-type transistor are thus formed. The P-type impurities B are implanted at 2.5 keV and 3E15 atoms/cm², for example.

Thereafter, heat treatment is performed in a non-oxidizing atmosphere to activate the impurities in the source region and the drain region. The heat treatment is performed preferably for 1 second or shorter at a temperature of 1,000° C. or higher and 1,100° C. or lower. In this heat treatment step, Hf is diffused from the Hf layer 117 into the upper electrode 120, the lower electrode 116, and the gate insulating film 114 in the LVT transistor forming region 101. Similarly, the heat treatment causes Hf to diffuse from the Hf layer 117 into the gate insulating film 114 and the gate electrode 121 in the HVT transistor forming region 103. With the progress of the diffusion, the Hf layer 117 in the HVT transistor forming region 103 reacts with Si and O that constitute the gate insulating film, and turns into the HfSiO layer 119. Through the process described above, the Hf concentration profiles illustrated in FIGS. 1B and 1C are obtained and the semiconductor device 100 illustrated in FIG. 1A is formed.

In the semiconductor device manufacturing method described above, the Hf layer 117 in the HVT transistor forming region 103 is formed between the gate insulating film 114 and the gate electrode 121, whereas the Hf layer 117 in the LVT transistor forming region 101 is formed in a location apart from the interface between the gate insulating film 114 and the lower electrode 116. This makes the Hf concentration at the gate insulating film-gate electrode interface higher in the HVT transistor 104 than in the LVT transistor 102 (FIGS. 1A and 1B).

Effects of this embodiment are described next.

In the semiconductor device 100, the Hf concentration at the interface between the gate insulating film 114 and the gate electrode 121 in the HVT transistor 104 is higher than the Hf concentration at the interface between the gate insulating film 114 and the gate electrode 126 in the LVT transistor 102. This allows the HVT transistor 104 to have a raised threshold voltage, and the impurity concentration in its channel region can therefore be reduced by an amount corresponding to the rise in threshold voltage. The impurity amount in the channel region of the LVT transistor 102 can be reduced as well because of Hf diffused so as to be present at the gate insulating film-gate electrode interface of the LVT transistor 102 in a small amount. Obtained as a result is a semiconductor device in which an LVT transistor and an HVT transistor on the same semiconductor substrate both have high-performance characteristics.

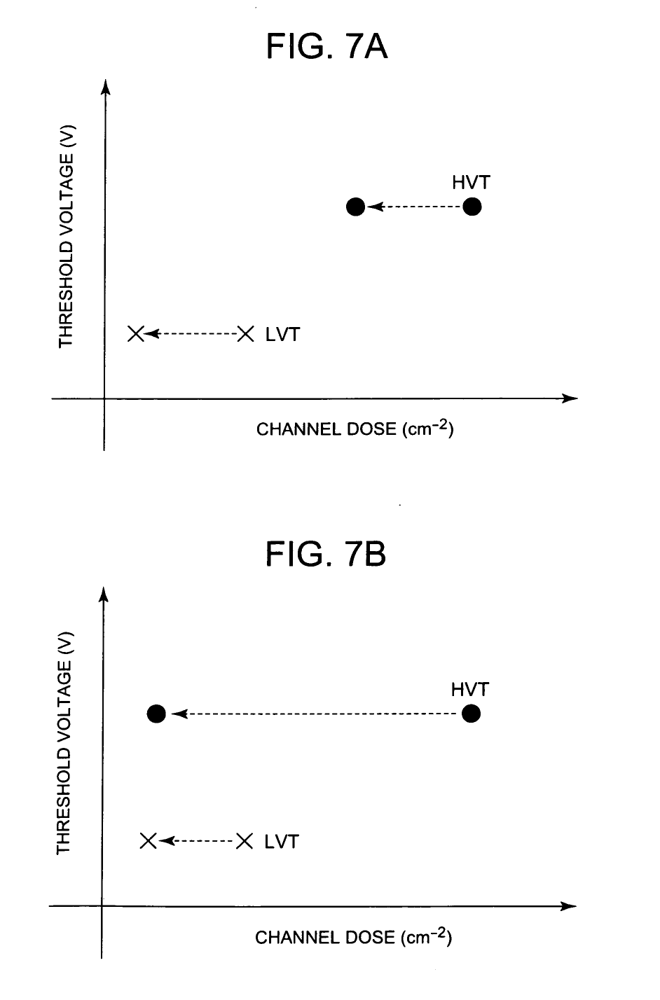

In addition, as schematically illustrated in FIG. 7B, the channel dose can be reduced significantly in the HVT transistor, and to substantially zero in the LVT transistor, by adjusting the amount of Hf layer adhered and heat treatment conditions. This effect cannot be obtained by applying the method of JP 2006-93670 A to a semiconductor device that includes an LVT transistor and an HVT transistor on the same substrate, as is obvious from a comparison between FIG. 7A and FIG. 7B.

The presence of Hf elements at the interface between a gate insulating film that is made of SiON and a gate electrode that is made of polysilicon raises the threshold voltage of an FET. The mechanism is deduced to have a basis in the following principle. When Hf elements are present at the interface between a gate insulating film made of SiON and a gate electrode made of polysilicon, Hf bonds with Si in the polysilicon film at the interface, forming Hf—Si bonds on the surface of the gate electrode. Fermi level pinning occurs at the interface as a result. In the case of Hf, the Fermi level is formed at a point that is apart from the conduction band of Si by 0.3 eV. The pinning causes depletion in the gate electrode, thereby raising the threshold voltage of the FET.

In the structure of the present invention, the Hf content in the HfSiO layer 119 of the HVT transistor 104 of the semiconductor device 100 is larger than in JP 2006-93670 A. The HVT transistor of the present invention is therefore improved in effective gate insulating film dielectric constant compared to the transistor of JP 2006-93670 A.

The semiconductor device according to the present invention is not limited to the semiconductor device of the embodiment described above, and various modifications can be made. For instance, while the embodiment described above shows an example in which the transistors are P-channel MOSFETs, the structure of the present invention is also effective when the transistors are N-channel MOSFETs.

Depending on the design value of the threshold voltage, Hf in the LVT transistor 102 does not need to be diffused so far as the interface between the gate insulating film and the gate electrode if the amount of Hf layer adhered, the thickness of the lower electrode 116, and heat treatment conditions are adjusted.

What is claimed is:

1. A semiconductor device comprising, on the same semiconductor substrate:
a first field effect transistor; and
a second field effect transistor, which is higher in threshold voltage than the first field effect transistor,
wherein the first field effect transistor comprises:
a first gate insulating film formed on the semiconductor substrate; and
a first gate electrode formed on the first gate insulating film,
wherein the first gate electrode contains at least one metal element selected from the group consisting of Hf, Zr, Al, La, Pr, Y, Ta, and W,
wherein the second field effect transistor comprises:
a second gate insulating film formed on the semiconductor substrate; and
a second gate electrode formed on the second gate insulating film,
wherein the second gate insulating film and the second gate electrode contain the at least one metal element, and
wherein concentration of the at least one metal element at an interface between the second gate insulating film and the second gate electrode is higher than concentration of the at least one metal element at an interface between the first gate insulating film and the first gate electrode.

2. The semiconductor device according to claim 1,
wherein, in the first field effect transistor, the concentration of the at least one metal element peaks in a location within the first gate electrode that is apart from the interface between the first gate insulating film and the first gate electrode, and
wherein, in the second field effect transistor, the concentration of the at least one metal element peaks between the second gate insulating film and the second gate electrode.

3. The semiconductor device according to claim 2, wherein the at least one metal element in the first gate electrode has a concentration profile in which the concentration of the at least one metal element decreases from the location apart from the interface between the first gate insulating film and the first gate electrode where the concentration of the at least one metal element peaks, toward the semiconductor substrate, and toward a top surface of the first gate electrode, and
wherein the at least one metal element in the second gate insulating film has a concentration profile in which the concentration of the at least one metal element decreases from a top surface of the second gate insulating film toward the semiconductor substrate, and the at least one metal element in the second gate electrode has a concentration profile in which the concentration of the at least one metal element decreases from a bottom surface of the second gate electrode toward a top surface of the second gate electrode.

4. The semiconductor device according to claim 1,
wherein the first gate insulating film and the second gate insulating film comprise silicon oxide films, and
wherein the first gate electrode and the second gate electrode are formed from silicon.

5. The semiconductor device according to claim 4, wherein the first gate insulating film and the second gate insulating film are formed from SiON.

6. The semiconductor device according to claim 4,
wherein the at least one metal element is Hf, and
wherein the second field effect transistor further comprises a HfSiO layer interposed between the second gate insulating film and the second gate electrode.

7. The semiconductor device according to claim 5,
wherein the at least one metal element is Hf, and
wherein the second field effect transistor further comprises a HfSiO layer interposed between the second gate insulating film and the second gate electrode.

8. The semiconductor device according to claim 2, wherein, in the first gate electrode, the concentration of the at least one metal element peaks in a location that is apart from the interface between the first gate insulating film and the first gate electrode by 3 nm or more and 20 nm or less.

9. A method of manufacturing a semiconductor device in which a first field effect transistor and a second field effect transistor, which is higher in threshold voltage than the first field effect transistor, are formed on the same semiconductor substrate,
the method comprising:
forming a gate insulating film in a first field effect transistor forming region and a second field effect transistor forming region on the semiconductor substrate;
forming a first electrode layer in the first field effect transistor forming region alone;
forming in the first field effect transistor forming region and the second field effect transistor forming region a layer of at least one metal element selected from the group consisting of Hf, Zr, Al, La, Pr, Y, Ta, and W;
forming a second electrode layer in the first field effect transistor forming region and the second field effect transistor forming region; and
subjecting the semiconductor substrate to heat treatment.

10. The method of manufacturing a semiconductor device according to claim 9,
wherein the gate insulating film comprises a silicon oxide film, and
wherein the first electrode layer and the second electrode layer are formed from silicon.

11. The method of manufacturing a semiconductor device according to claim 10, wherein the gate insulating film is formed from SiON.

12. The method of manufacturing a semiconductor device according to claim 9, wherein the first electrode layer has a thickness of 3 nm or more and 20 nm or less.

13. The method of manufacturing a semiconductor device according to claim 9, wherein an amount of the at least one metal element adhered in the forming the layer of the at least one metal element is 1×10¹³ atoms/cm² or more and 3×10¹⁵ atoms/cm² or less in surface concentration.
